(19) United States
(12) Patent Application Publication
(10) Pub. No.: US 2021/0102287 A1
(43) Pub. Date: Apr. 8, 2021

(54) THIN FILM DEPOSITION APPARATUS AND THIN FILM DEPOSITION METHOD

(71) Applicant: EUGENE TECHNOLOGY CO., LTD., Yongin-si (KR)

(72) Inventors: Kwang Woon LEE, Gwangmyeong-Si (KR); Kang Il LEE, Yongin-Si (KR); Kyu Jin CHOI, Seongnam-Si (KR); Min Hyuk IM, Hwaseong-Si (KR); Sung Ha CHOI, Suwon-Si (KR)

(21) Appl. No.: 17/033,664

(22) Filed: Sep. 25, 2020

(30) Foreign Application Priority Data
Oct. 8, 2019 (KR) 10-2019-0124655

(51) Int. Cl. C23C 16/44; C23C 16/34

(52) U.S. Cl. CPC C23C 16/4402; C23C 16/34

(57) ABSTRACT

The present invention relates to a thin film deposition apparatus and a thin film deposition method in which the resistivity of a thin film is decreased by reducing the content of impurities inside a thin film. The thin film deposition apparatus may include a process chamber configured to perform a deposition process for causing a first metal and a reactant source to react, to form a thin film on a substrate; a source gas nozzle part configured to supply, into the process chamber, a source gas including the first metal and a ligand; a pretreatment gas nozzle part configured to supply, into the process chamber, a pretreatment gas including a second metal reactable with the ligand; and a reaction gas nozzle part configured to supply, into the process chamber, a reaction gas comprising the reactant source.

### CROSS-REFERENCE TO RELATED APPLICATION

This application claims priority to Korean Patent Application No. 10-2019-0124655 filed on Oct. 8, 2019 and all the benefits accruing therefrom under 35 U.S.C. § 119, the contents of which are incorporated by reference in their entirety.

### BACKGROUND

The present disclosure relates to a thin film deposition apparatus and a thin film deposition method, and more particularly, to a thin film deposition apparatus and a thin film deposition method, with which the resistivity of a thin film is reduced by reducing impurity concentration in the thin film.

In the semiconductor industries, thin films used for semiconductor devices have been deposited using a method such as an atomic layer deposition (ALD) method or a chemical vapor deposition (CVD) method. At this point, metallic precursor compounds including deposition metals and ligands (or bonding elements) have been mainly used as a source gas for thin film deposition.

In typical arts, when depositing a thin film using a metallic precursor compound, the bond between a deposition metal and a ligand is not effectively disconnected, so that the deposition metal is deposited in a state bonded with a portion of the ligand, and thus, the thin film contains the ligand which may act as impurity, and there is caused a limitation of increasing the resistivity of the thin film.

Recently, as high performance and high integration of semiconductor devices have been required and the sizes of the devices have decreased, a technology for improving the resistivity characteristics of thin films used for semiconductor devices is being demanded.

### PRIOR ART DOCUMENT

### Patent Document

### Korean Patent No. 10-0642763

### SUMMARY

The present disclosure provides a thin film deposition apparatus and a thin film deposition method, with which the resistivity of a thin film is reduced by suppressing or preventing intrusion of impurities such as ligands into a thin film while using a source gas including the ligands.

In accordance with an exemplary embodiment, a thin film deposition apparatus includes: a process chamber configured to perform a deposition process for causing a first metal and a reactant source to react, to form a thin film on a substrate; a source gas nozzle part configured to supply, into the process chamber, a source gas including the first metal and a ligand; a pretreatment gas nozzle part configured to supply, into the process chamber, a pretreatment gas including a second metal reactable with the ligand; and a reaction gas nozzle part configured to supply, into the process chamber, a reaction gas including the reactant source.

The reaction gas nozzle part may supply the reaction gas in a manner temporally separate from the source gas and the pretreatment gas.

The pretreatment gas nozzle part may supply the pretreatment gas during at least a portion of a time period when the source gas nozzle part supplies the source gas.

The second metal may have greater bonding energy with the ligand than the first metal.

A supply amount of the pretreatment gas per unit time may be greater than a supply amount of the source gas per unit time.

In accordance with another exemplary embodiment, a thin film deposition method may include: supplying a source gas including a first metal and a ligand into a process chamber to which a substrate is supplied; supplying a pretreatment gas including a second metal reactable with the ligand into the process chamber; and supplying, into the process chamber, a reaction gas including a reactant source which reacts with the first metal and forms a thin film.

The supplying of the source gas and the supplying of the reaction gas may be alternately performed.

The thin film deposition method may further include supplying a purge gas into the process chamber between the supplying of the source gas and the supplying of the reaction gas.

The supplying of the pretreatment gas into the processing chamber may be performed during at least a portion of a time period for supplying of the source gas while performing the supplying the source gas.

The supplying of the pretreatment gas into the process chamber may be performed while supplying a greater supply amount of the pretreatment gas than the source gas.

The supplying of the source gas may be performed for a longer time period than the supplying of the pretreatment gas into the processing chamber.

The supplying of the source gas may be performed for a longer time period than the supplying of the pretreatment gas into the processing chamber.

The second metal may have greater bonding energy with the ligand than the first metal.

In accordance with yet another exemplary embodiment, a thin film deposition method includes: supplying a source gas including titanium (Ti) and a ligand into a process chamber to which a substrate is loaded; supplying a pretreatment gas including silicon (Si) reactable with the ligand into the process chamber; and supplying, into the process chamber, a reaction gas including a nitrogen atom (N) which reacts with titanium (Ti) and forms a titanium nitride (TiN) thin film.

### BRIEF DESCRIPTION OF THE DRAWINGS

Exemplary embodiments can be understood in more detail from the following description taken in conjunction with the accompanying drawings, in which:

FIG. 1 is a cross-sectional view of a thin film deposition apparatus in accordance with an exemplary embodiment;

FIG. 2 is a horizontal sectional view of a thin film deposition apparatus in accordance with an exemplary embodiment;

FIG. 3 is a graph for describing a supply cycle of a source gas, a pretreatment gas, a reaction gas, and an atmosphere gas in accordance with an exemplary embodiment;

FIG. 4 is a view for describing changes in resistivity according to a time for simultaneously supplying a source gas and a pretreatment gas in accordance with an exemplary embodiment; and

FIG. 5 is a flowchart illustrating a thin film deposition method in accordance with another embodiment of the present invention.

### DETAILED DESCRIPTION OF EMBODIMENTS

Hereinafter exemplary embodiments will be described in detail with reference to the accompanying drawings. However, the present invention may, however, be embodied in different forms and should not be construed as limited to the embodiments set forth herein. Rather, these embodiments are provided so that this disclosure will be thorough and complete, and will fully convey the scope of the present invention to those skilled in the art. In descriptions, like reference numerals refer to like configurations, figures may be partially exaggerated for clarity of illustration of exemplary embodiments, and like reference numerals refer to like elements in figures.

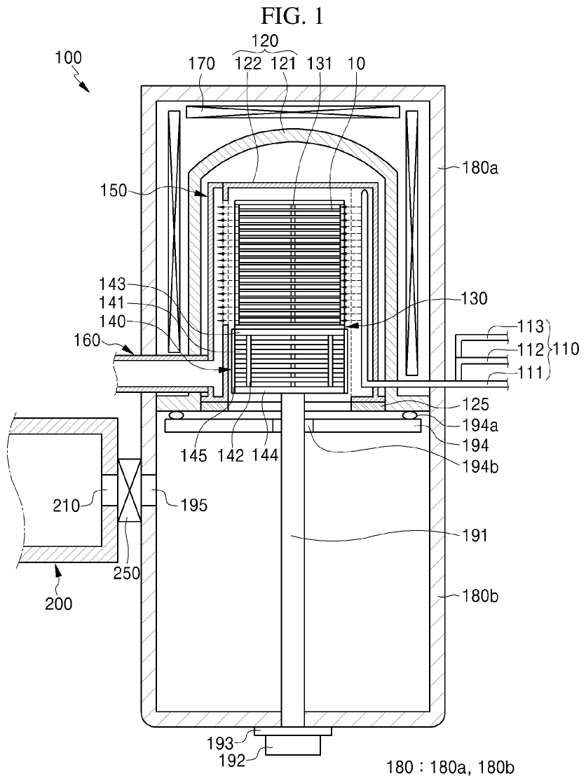

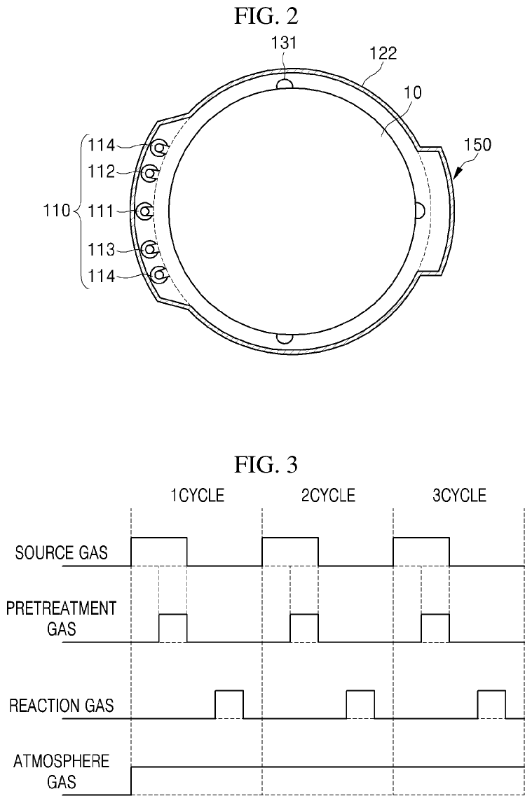

FIG. 1 is a cross-sectional view of a thin film deposition apparatus in accordance with an exemplary embodiment and FIG. 2 is a horizontal sectional view of a thin film deposition apparatus in accordance with an exemplary embodiment.

Referring to FIGS. 1 and 2, a thin film deposition apparatus 100 in accordance with an exemplary embodiment may include: a process chamber 180 configured to perform a deposition process for causing a first metal and a reactant source to react, to form a thin film on a substrate 10; a source gas nozzle part 111 configured to supply a source gas including the first metal and a ligand into the process chamber 180; a pretreatment gas nozzle part 112 configured to supply, into the process chamber 180, a pretreatment gas including a second metal reactable with the ligand; and a reaction gas nozzle part 113 configured to supply, into the process chamber 180, a reaction gas including the reactant source.

In the process chamber 180, a deposition process may be performed in which the first metal (or transition metal) and the reactant source are caused to react on the substrate 10 to form a thin film. The process chamber 180 may be of a single wafer type for processing the substrate 10 one by one, and of a batch type for stacking a plurality of substrates 10 on a substrate boat 130 in a multistage and simultaneously processing the substrates. Here, the first metal may be a deposition metal or a metallic precursor.

For example, in case of the batch type, the process chamber 180 may be composed of an upper chamber 180a and a lower chamber 180b which communicate with each other, and a reaction tube 120 for providing a process space, in which the substrate boat 130 is accommodated and a deposition process may be performed on the substrate 10, may be disposed inside the process chamber 180. At this point, the reaction tube 120 may be composed of a single tube or a plurality of tubes, as long as the process space in which the substrate boat 130 is accommodated and a deposition process may be performed on the substrate 10. For example, the reaction tube 120 may be composed of an outer tube 121 and an inner tube 122. Here, a lower portion of the inner tube 122 may be connected to and supported on a flange part 125, and the structure and shape of the inner tube 122 are not limited thereto but diversified.

Meanwhile, in the substrate boat 130, slots may be formed in multistage on a plurality of rods 131 so that the substrate 10 is inserted and loaded. In addition, the substrate boat 130 may be configured such that an isolation plate (not shown) is disposed on or under the substrate 10, and the isolation plate (not shown) is coupled to the plurality of rods 131 in multistage so that individual processing space may be provided for each substrate 10. In addition, the substrate boat 130 may rotate during a deposition process, and ceramic, quartz, synthetic quartz or the like may be used as the material for the substrate boat 130 including the isolation plate (not shown), but the shape and material for the substrate boat 130 are not limited thereto and be diversified.

The source gas nozzle part 111 may supply, into the process chamber, a source gas including the first metal and the ligand, deposit the first metal (layer) on the substrate 10, and deposit a first metal atomic layer (or unit layer) in case of an atomic layer deposition (ALD). Here, the source gas may be a metallic precursor compound, the ligand may be a common name of ions (or atoms) bonded to the first metal in the metallic precursor compound, and be a bonded element bonded with the first metal. Meanwhile, the first metal may include a transition metal such as titanium (Ti), tantalum (Ta), chromium (Cr), zirconium (Zr), tungsten (W), nickel (Ni), copper (Cu), or zinc (Zn), but the embodiment is not limited thereto as long as a metal that may deposit a thin film in a nitride film or an oxide film.

The pretreatment gas nozzle part 112 may supply, into the process chamber 180, a pretreatment gas including a second metal (or metalloid) reactable with the ligand. The second metal may react and bonded with the ligand by supplying the pretreatment gas into the process chamber 180 through the pretreatment gas nozzle part 112, and the second metal is bonded with the ligand and thus the bonding between the first metal and the ligand may be disconnected. Accordingly, the bonding between the first metal and the ligand may be effectively disconnected in the source gas, and the first metal may be suppressed or prevented from being deposited in a state of being bonded with the ligand. Here, the second metal may be a substitute metal and react with the ligand, and include a metalloid such as silicon (Si) and germanium (Ge), but the embodiment is not limited thereto, as long as a metal reactable with the ligand.

The reaction gas nozzle part 113 may supply a reaction gas including the reactant source into the process chamber 180, and cause the reactant source to react with the first metal (layer) on the substrate 10 to form the thin film (that is, a desired thin film). Here, the reactant source may include a nitrogen (N) atom or an oxygen (O) atom, and the thin film may be a nitride film or an oxide film in which the first metal is nitrified or oxidized.

Such the source gas nozzle part 111, the pretreatment gas nozzle part 112 and the reaction gas nozzle part 113 may forma gas supply part 110. At this point, when the thin film deposition apparatus 100 is of a batch type, the gas supply part 110 may be disposed on one side of the inner tube 122, and an exhaust duct 150 may extend in the vertical direction on the other side facing the one side in the inner tube 122 and may discharge (or remove) residue gas and/or deposition byproducts inside the inner tube 122. Meanwhile, the gas supply part 110 and the exhaust part 150 are positioned facing each other (or symmetrical to each other), so that a laminar flow may be formed on the substrate 10.

FIG. 3 is a graph for describing a supply cycle of a source gas, a pretreatment gas, a reaction gas, and an atmosphere gas in accordance with an exemplary embodiment.

Referring to FIG. 3, the reaction gas nozzle part 113 may supply the reaction gas at a temporally separated time with respect to the source gas and the pretreatment gas. When the reaction gas is supplied together with the pretreatment gas, the second metal included in the pretreatment gas reacts with the reaction gas and thus a byproduct film (that is, undesired thin film) may be formed. In addition, when the reaction gas and the source gas are supplied together, the first metal in the source gas may react with the reactant source before the ligand is disconnected from the source gas, and the thin film may be formed on the first metal in a state of being bonded with the ligand. Accordingly, the ligand is included in the thin film and act as an impurity and the resistivity of the thin film may be increased. In addition, the first metal and the reactant source do not react on the uppermost layer (uppermost surface) on the substrate 10, but react in the air above the substrate 10, and thus, the coupling power (or, the formed suction force of the substrate with respect to the substrate) between the formed thin film and the substrate 10 may be weakened.

However, when the reaction gas is supplied at the temporally separated time with respect to the source gas and the pretreatment gas, the second metal may react with the reaction gas and prevent the formation of the byproduct film, and cause only the first metal deposited on the substrate 10 to react with the reaction gas.

Meanwhile, the thin film may be deposited through a method such as an atomic layer deposition (ALD) method or a chemical vapor deposition (CVD) method, and may be deposited while supplying the reaction gas at a temporally separated time with respect to the source gas and the pretreatment gas.

The pretreatment gas nozzle part 112 may supply the pretreatment gas during a portion of a time period when the source gas nozzle part 111 supplies the source gas, and the pretreatment gas may be supplied together with the source gas for a certain time period (or predetermined time period). The pretreatment gas function to separate the first metal and the ligand by disconnecting the bonding between the first metal and the ligand before the first metal is deposited on the substrate 10, and therefore the pretreatment gas needs to be supplied together (co-flow) with the source gas. To this end, the pretreatment gas may be supplied during at least a portion of the time period for supplying the source gas. Accordingly, the first metal and the ligand are separated before the first metal is deposited on to the substrate 10, so that the first metal deposited in a state of being bonded with the ligand may be minimized.

At this point, the time period for supplying the pretreatment gas may be shorter than the time period for supplying the source gas, and before the source gas and the pretreatment gas are supplied together (co-flow), the first metal may be deposited on the substrate 10 earlier than the second metal by supplying only the source gas. Accordingly, it is not only possible to cause the second metal not to be deposited on the substrate 10 but to react with the ligand, but also possible to prevent the second metal from being deposited on the substrate 10. That is, the second metal may also be an atom (or matter) that may be deposited on the substrate 10. Thus, when the source gas and the pretreatment gas are started to be supplied together, the second metal may be deposited on the substrate 10 and react with the reaction gas to form the byproduct film. In addition, the second metal is contained in the thin film and act as an impurity.

However, when only the source gas is first supplied for a certain time period (or predetermined time period), it is possible to induce such that the first metal (layer) is first deposited on the substrate 10 and only the first metal is deposited on the substrate 10. In addition, not only the ligand may be suppressed or prevented from being contained in the thin film by causing the second metal to disconnect, through the bonding with the ligand, the bonded ligand from the first metal that has been deposited in a state of being bonded with the ligand, but also the second metal may be prevented from being deposited on the substrate 10. Accordingly, the second metal may be induced to react only with the ligand, and the bonding product generated by the reaction (bonding) of the second metal and the ligand may be discharged from the inside (or inside of the inner tube) of the process chamber 180.

Meanwhile, the gas supply part 110 may further include a purge gas nozzle part 114 configured to supply a purge gas. The purge gas nozzle part 114 may supply a purge gas, and purge and discharge the residue gas of source gas, the pretreatment gas and/or the reaction gas from the inside of the process chamber 180. At this point, the purge gas may include a nitrogen (N₂) gas, or an inert gas such as argon (Ar), helium (He) or neon (Ne). In addition, the purge gas nozzle part 114 may be symmetrically disposed on both sides with the source gas nozzle part 111, the pretreatment gas nozzle part 112 and the reaction gas nozzle part 113 therebetween, and may adjust the injection range (or area) of each gas (that is, the source gas, the pretreatment gas, and the reaction gas).

In addition, the controlled atmosphere gas illustrated in FIG. 3 is a gas for adjusting the atmosphere inside the process chamber 180 and may adjust the internal pressure of the process chamber 180, and a nitrogen (N₂) gas or an inert gas such as argon (Ar), helium (He) or neon (Ne) may be used as the atmosphere gas. In addition, in order to carry, into the process chamber 180, any one gas among the source gas, the pretreatment gas, or the reaction gas, a carrier gas may be used, and a nitrogen (N₂) gas or an inert gas such as argon (Ar), helium (He) or neon (Ne) may be used as the carrier gas corresponding to the atmosphere gas. Here, the carrier gas may be used to carry a vapor-state raw material after vaporizing the liquid-state raw material into a vapor state. Meanwhile, the purge gas may also be determined corresponding to the atmosphere gas.

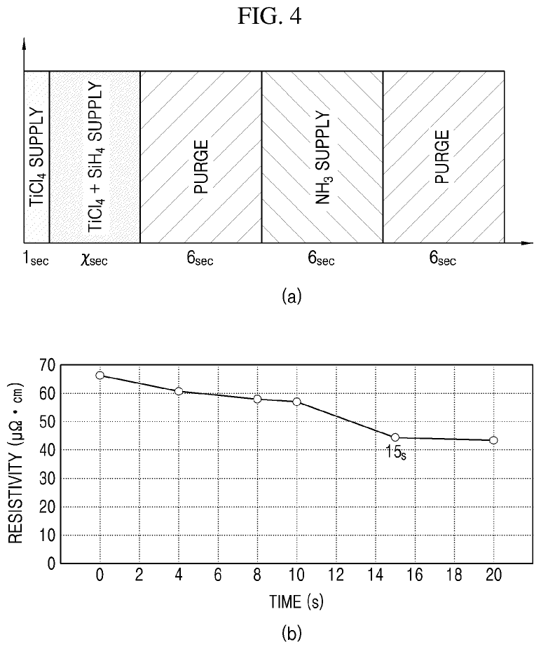

FIG. 4 is a view for describing changes in resistivity according to a time for simultaneously supplying a source gas and a pretreatment gas in accordance with an exemplary embodiment, (a) of FIG. 4 illustrates the supply sequence of a process gas, and (b) of FIG. 4 is a resistivity graph according to a simultaneous supply time of a source gas and a pretreatment gas.

Referring to FIG. 4, titanium tetrachloride (TiCl₄) may be used as the source gas, silane SiH₄ may be used as the pretreatment gas, and ammonia NH₃ may be used as the reaction gas. At this point, titanium (Ti) as the first metal (or deposition metal) and nitrogen atom (N) as a reactant source, react and form (or deposit) a titanium nitride (TiN) thin film. In addition, silicon (Si) as the second metal may act as a substitute metal and be bonded with a chlorine (Cl) element as a ligand to generate SiClₓ (e.g. SiCl₂), and the bonding between the titanium (Ti) and the chlorine (Cl) element is disconnected, so that the titanium (Ti) may be separated from the chlorine (Cl) element. Here, the substitute metal means a metal which is bonded with the ligand bonded to another metal (atom), disconnects the bond with the another metal, and thereby substitutes (replaces) the metal (atom) or the center atom to which the ligand is bonded. In addition, the SiClₓ which is a bonded product of the silicon (Si), which is the second metal, and the chlorine element (Cl), which is the ligand, may be in a gas phase, and be discharged from the inside of the process chamber through purging and/or exhaust. In addition, hydrogen element (H) bonded to the silicon (Si) which is the second metal may be separated from the silicon (Si) and present in a gas state (that is, H₂), or bonded to the chlorine element (Cl) and present as gas-state hydrogen chloride (HCl). At this point, hydrogen (H₂) and/or hydrogen chloride (HCl) may also be discharged from the inside of the process chamber 180 through purging and/or exhaust.

Table 1 illustrates bonding energy between the chlorine element (Cl) and titanium (Ti) and bonding energy between the chlorine element (Cl) and silicon (Si).

TABLE 1

| | Bonding energy (D⁰₂₉₈/kJ · mol⁻¹) |
|---|---|
| Cl—Ti | 405.4 ± 10.5 |
| Cl—Si | 416.7 ± 6.3 |

Referring to FIG. 4 and Table 1, the second metal may have greater bonding energy with the ligand than the first metal. Large bonding energy between each other means that bonding is well established and is not easily disconnected, and small bonding energy means that bonding power is weak and is easily disconnected. In addition, when the bonding energy between each other is large, bonding between each other may be (more) stabilized, and conditional energy may thereby be lowered and a low condition of energy may be achieved. The bonding energy between the second metal (e.g. Si) and the ligand (e.g. Cl) may be relatively greater than the bonding energy between the first metal (e.g. Ti) and the ligand (e.g. Cl). Therefore, the second metal reacts and is bonded with the ligand while the pretreatment gas (e.g. SiH₄) is supplied, so that a bonding product (e.g. SiCl₂) may be generated and the bonding between the first metal and the ligand which has relatively weak bonding energy may be disconnected. Accordingly, the first metal may be separated from the ligand.

Here, the second metal may be bonded with the ligand and generate a gas-phase bonding product and the product may be discharged from the inside of the process chamber 180 through purging and/or exhaust.

For example, the thin film deposition apparatus in accordance with an exemplary embodiment may deposit a titanium nitride (TiN) thin film, the source gas maybe TiCl₄, the pretreatment gas may be silane (SiH₄), and the reaction gas may be ammonia (NH₃). At this point, the SiClₓ which is a bonding product may be more stabilized than TiCl₄ and/or silane (SiH₄) and have a lower energy state.

The supply amount of the pretreatment gas per unit time may be greater than the supply amount of the source gas per unit time. The source gas is supplied into the process chamber 180 in a gas phase or a vapor phase, and the source gas may have more number of atoms of the ligand which is a non-metal than the first metal which is a metal. In addition, in order to disconnect the bonding between the first metal and the ligand by being bonded with the ligand, the second metal which is a metal different from the first metal should be used. Here, the second metal may be included in the gas-phase or vapor-phase pretreatment gas such that only one atom is included per molecule, and thus, in order to supply the second metal corresponding to the ligand which has many atoms, the supply amount of the pretreatment gas per unit time have to be increased compared to the supply amount of the source gas per unit time. That is, the supply amount of the pretreatment gas per unit time is increased compared to the supply amount of the source gas per unit time, so that all the ligand in the source gas may be configured to maximally react and be bonded with the second metal. Accordingly, all the first metal may maximally be separated from the ligand, generate a bonding product of the second metal and the ligand, and discharge the bonding product from the inside of the process chamber 180.

For example, the source gas (e.g. TiCl₄) may be supplied in a supply amount of approximately 0.1 to 1 slm. In addition, the pretreatment gas (e.g. SiH₄) may be supplied in an amount of no more than approximately 2 slm and be supplied in a greater amount (or, supply amount per unit time) than the supply amount (or supply amount per unit time) of the source gas. Here, the slm refers to a standard litters per minute, and indicates litters (flow rate) per minute in a standard state.

At this point, the ratio of the supply amount of the pretreatment gas to the supply amount of the source gas per unit time may be no more than approximately 1:10. That is, the supply amount of the pretreatment gas per unit time may not exceed approximately 10 times the supply amount of the source gas per unit time. When the supply amount of the pretreatment gas per unit time exceeds approximately 10 times the supply amount of the source gas per unit time, the second metal becomes more than the ligand and the second metal may be deposited on the substrate 10 and act as an impurity in the thin film.

Meanwhile, in order to supply the second metal (e.g. Si) in a gas phase or a vapor phase, the pretreatment gas (e.g. SiH₄) may include a non-metal element (or gas element) such as hydrogen (H) bonded with the second metal. The pretreatment gas may be separated from the second metal and present in a gas state (e.g. H₂), or be bonded with the ligand (e.g. Cl) and present as a composite gas (e.g. HCl). Here, the non-metal element and/or the composite gas may also be discharged from the inside of the process chamber 180 through purging and/or exhaust. That is, the pretreatment gas may be composed of the second metal that may react with the ligand and generate a bonding product and a gas element bonded with the second metal.

In addition, referring to FIG. 3, a single cycle may mean that only the source gas is supplied for a certain time period (or predetermined time period), and after the source gas and the pretreatment gas are supplied together (co-flow) for a certain time period, the reaction gas is supplied. Here, a plurality of cycles (or periods) may be repeated and the thin film with a desired thickness may be deposited (or formed).

Referring again to (a) of FIG. 4, after the source gas and the pretreatment gas are supplied together (co-flow) for a certain time period, the purge gas is supplied, and thus, the inside of the process chamber 180 may be purged. Here, the atmosphere gas may be continuously supplied, and the same gas as the atmosphere gas may be used as the purge gas.

Referring to (b) of FIG. 4, the greater the time period for supplying the source gas and the pretreatment gas together (co-flow), the smaller the resistivity of the thin film may be. That is, as the time period for supplying together (co-flow) the source gas and the pretreatment gas increases, the resistivity of the thin film may be decreased with respect to the same thickness.

The thin film deposition apparatus 100 according to an exemplary embodiment may further include a pedestal 140 which is connected to a lower end section of the substrate boat 130 and supports the substrate boat 130. The pedestal 140 may be connected to the lower end of the substrate boat 130 and support the substrate boat 130, move up and down together with the substrate boat 130, and be accommodated in a lower end section of the accommodating space of the inner tube 122 during a deposition process. In addition, the pedestal 140 may include a plurality of heat shield plates 141 disposed spaced apart from each other in multiple stages. The plurality of heat shield plate 141 may be connected to a plurality of supporters 142 and be disposed in multiple stages and be spaced apart from each other. At this point, the plurality of heat shield plate 141 may be configured as a baffle plate for preventing heat transfer in the vertical direction, and be composed of a material (e.g. opaque quartz) with low heat conductivity.

In addition, the pedestal 140 extends in the vertical direction and may further include: a plurality of supporters 142; an upper plate 143 and a lower plate 144 which respectively fix the upper and lower ends of the plurality of supporters 142; and a side cover 145 which surrounds the side surfaces of the plurality of heat shield plates 141. The plurality of supporters 142 may extend in the vertical direction, be disposed spaced apart from each other in the horizontal direction, and support the plurality of heat shield plates 141.

The upper plate 143 may fix the upper ends of the plurality of supporters 142 and be connected to the substrate boat 130. The lower plate 144 may fix the lower ends of the plurality of supporters 142 and be connected (or coupled) to a shaft 191. Here, the upper plates 143 and the lower plates 144 of the plurality of supporters 142 may form the skeleton of the pedestal 140.

The side cover 145 may be formed so as to surrounding the side surface (or the side surfaces of the pedestal) of the plurality of heat shield plates 141 and be connected and fixed to the upper plates 143 and/or lower plates 144.

The thin film deposition apparatus 100 according to an exemplary embodiment may further include an exhaust port communicating with an exhaust duct 150. The exhaust port 160 may communicate with a lower portion of the exhaust duct 150, and accordingly, the residue gas introduced to one end (or one side) of the exhaust port 160 communicating with the exhaust duct 150 may move to the other end (or the other side) along the exhaust port 160 and be discharged to the outside. For example, the residue gas may be discharged by an exhaust pump (not shown) connected directly or indirectly to the exhaust port 160, and an exhaust pipe (not shown), which may extend an exhaust path between the exhaust port 160 and the exhaust pump (not shown), may also be provided.

The thin film deposition apparatus 100 according to an exemplary embodiment may further include a heater part 170 which provides thermal energy into the process chamber 180 (or into the inner tube). The heater part 170 may extend in the vertical direction outside the inner tube 122 and heat the inner tube 122, and may be disposed so as to surround the side surface and an upper portion of the inner tube 122 or the outer tube 121. At this point, the internal temperature of the process chamber 180 may be approximately 600° C. or lower, and a deposition process may favorably be performed at a temperature of approximately 400-500° C.

Meanwhile, a deposition process may be performed under a process conditions having an air pressure of no higher than approximately 10 Torr and a process temperature of no higher than approximately 500° C. so that the silicon atom (Si) of the silane (SiH₄) used as the pretreatment gas and the chlorine atom (Cl) of TiCl₄ used as the source gas are well bonded and effectively generate silicon chloride (e.g. SiCl₂) and the titanium atom (Ti) and the chlorine atom (Cl) may be smoothly separated in the TiCl₄.

The thin film deposition apparatus 100 according to an exemplary embodiment may further include: a shaft 191 connected to the lower plate 144 of the pedestal 140; a raising and lowering drive part 192 which is connected to the lower end of the shaft 191 and vertically moves the shaft 191; a rotary drive part 193 which is connected to the lower end of the shaft 191 and rotates the shaft 191; a support plate which is connected to the upper end of the shaft 191 and moves up and down together with the substrate boat 130; a sealing member 194a provided between the inner tube 122 or the outer tube 121 and the support plate 194; a bearing member 194b provided between the support plate 194 and the shaft 191; and an insertion opening 195 through which the substrate 10 is loaded into the process chamber 180.

The shaft 191 may be connected to the lower plate 144 of the pedestal 140 and function to support the pedestal 140 and/or the substrate boat 130.

The raising and lowering drive part 192 may be connected to the lower end of the shaft 191 and vertically move the shaft 191, and thereby raise and lower the substrate boat 130.

The rotary drive part 193 may be connected to the lower end of the shaft 191 so as to rotate the substrate boat 130, rotate the shaft 191, and thereby rotate the substrate boat 130 around the shaft 191.

The support plate 194 may be connected to the upper end of the shaft 191 and move up and down together with the substrate boat 130, and may function to seal the accommodation space of the inner tube 122 and/or the inner space of the outer tube 121 when the substrate boat 130 is accommodated in the accommodation space of the inner tube 122.

The sealing member 194a may be provided between the support plate 194 and the inner tube 122 and/or between the support plate 194 and the outer tube 121, and seal the accommodation space of the inner tube 122 and/or the inner space of the outer tube 121.

The bearing member 194b may be provided between the support plate 194 and the shaft 191 and rotate in a state in which the shaft 191 is supported by the bearing member 194b.

The insertion opening 195 may be provided on one side (e.g. one side of the lower chamber) of the process chamber 180, and the substrate 10 may be loaded into the process chamber 180 through the insertion opening 195 in a transfer chamber 200. An introducing opening 210 may be formed one side of the transfer chamber 200 corresponding to the insertion opening 195 of the process chamber 180, and a gate valve 250 may be provided between the introducing opening 210 and the insertion opening 195. Accordingly, the inside of the transfer chamber 200 and the inside of the process chamber 180 may be separated by the gate valve 250, and the introducing opening 210 and the insertion opening 195 may be opened/closed by the gate valve 250.

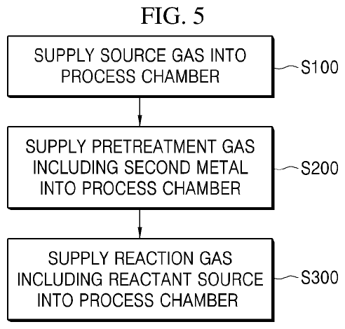

FIG. 5 is a flowchart illustrating a thin film deposition method in accordance with another embodiment of the present invention.

Referring to FIG. 5, a thin film deposition method in accordance with another exemplary embodiment will be described in detail, and matters that overlap the portion previously described about the thin film deposition apparatus in accordance with an exemplary embodiment will be omitted.

A thin film deposition method in accordance with another exemplary embodiment may include: step S100 for supplying a source gas including a first metal and a ligand into a process chamber to which a substrate is supplied; step S200 for supplying a pretreatment gas including a second metal reactable with the ligand into the process chamber; and step S300 for supplying, into the process chamber, a reaction gas including a reactant source which reacts with the first metal and forms a thin film.

First, a source gas including a first metal and a ligand is supplied into a process chamber to which a substrate is supplied (S100). A precursor compound including the first metal and the ligand may be supplied as the source gas into the process chamber, the first metal (layer) may be deposited on the substrate, and a first metal atom layer (or unit layer) may be deposited in the case of an atomic layer deposition (ALD).

Next, a pretreatment gas including a second metal reactable with the ligand is supplied into the process chamber (S200). The pretreatment gas including the second metal reactable with the ligand may be supplied into the process chamber. The second metal may be caused to react and bonded with the ligand by supplying the pretreatment gas into the process chamber to which the source gas is supplied. In addition, the second metal is bonded with the ligand and thus the bonding between the first metal and the ligand may be disconnected. Accordingly, the bonding between the first metal and the ligand may be effectively disconnected in the source gas, and the first metal may be suppressed or prevented from being deposited in a state of being bonded with the ligand.

Next, a reaction gas including a reactant source which reacts with the first metal and forms a thin film is supplied into the process chamber (S300). The reaction gas including the reactant source may be supplied into the process chamber, and the reactant source may be caused to react with the first metal (layer) on the substrate to form a thin film (that is, a desired thin film).

The step S100 for supplying the source gas and the step S300 for supplying the reaction gas may be alternately performed. That is, the source gas and the reaction gas may be supplied in a temporally separate manner. When the reaction gas and the source gas are supplied together, the first metal in the source gas may react with the reactant source of the reaction gas before the ligand is disconnected from the source gas, and the thin film may be formed on the first metal in a state of being bonded with the ligand. Accordingly, the ligand is included in the thin film and act as an impurity, and the resistivity of the thin film may be increased. In addition, the first metal and the reactant source do not react on the uppermost layer (uppermost surface) on the substrate 10 but react in the air above the substrate, so that the coupling power (or suction force of the formed substrate with respect to the substrate) between the formed thin film and the substrate may also be weakened.

However, when the reaction gas is supplied at a temporally separate time with respect to the source gas, only the first metal deposited on the substrate may be caused to react with the reactant source. Accordingly, the ligand may be suppressed or prevented from being contained in the thin film as an impurity, and may improve the resistivity of the thin film by reducing the resistivity of the thin film.

At this point, the reaction gas may be supplied in a temporally separate manner also with the pretreatment gas. When the reaction gas is supplied together with the pretreatment gas, the second metal included in the pretreatment gas reacts with the reaction gas, and thus a byproduct film (that is, undesired thin film) may be formed. However, when the reaction gas is supplied at a temporally separate manner with the pretreatment gas, the second metal may be prevented from reacting with the reaction gas and forming the byproduct film.

Step S250 for supplying a purge gas into the process chamber may further be included between the step S100 for supplying the source gas and the step S300 for supplying the reaction gas.

A purge gas may be supplied into the process chamber (S250). The source gas, the pretreatment gas and/or the residue gas of the reaction gas, and/or the deposition byproduct may be purged by supplying the purge gas into the process chamber and may be removed from the inside of the process chamber. At this point, the purge gas may include a nitrogen (N₂) gas, or an inert gas such as argon (Ar), helium (He) or neon (Ne). Accordingly, the step S100 for supplying the source gas and the step S300 for supplying the reaction gas may be reliably separated in time. In addition, the residue gas and/or the deposition byproduct may be removed through purging, and only the thin film formed by the reaction between the first metal and the reactant source react may remain (or be present) on the substrate, and thus, the impurities of the thin film may be minimized.

The step S200 for supplying the pretreatment gas into the process chamber may be performed during at least a portion of the time period for supplying the source gas while performing the step S100 for supplying the source gas. The pretreatment gas may be supplied during at least a portion of the time period for supplying the source gas, and the pretreatment gas may be supplied together with the source gas for a certain time period (or predetermined time period). The pretreatment gas function to separate the first metal and the ligand by disconnecting the bonding between the first metal and the ligand before the first metal is deposited on the substrate 10, and therefore the pretreatment gas needs to be supplied together (co-flow) with the source gas. To this end, the pretreatment gas may be supplied during at least a portion of the time period for supplying the source gas. Accordingly, the first metal and the ligand are separated before the first metal is deposited on to the substrate 10, so that the first metal deposited in a state of being bonded with the ligand may be minimized.

The step S200 for supplying the pretreatment gas into the process chamber may be performed while supplying a greater supply amount of the pretreatment gas than the source gas. The source gas is supplied into the process chamber in a gas phase or a vapor phase, and the source gas may have more number of atoms of the ligand, which is a non-metal, than the first metal which is a metal. In addition, in order to disconnect the bonding between the first metal and the ligand by being bonded with the ligand, the second metal which is a metal different from the first metal should be used. Here, the second metal may be included in the gas-phase or vapor-phase pretreatment gas such that only one atom is included per molecule, and thus, in order to supply the second metal corresponding to the ligand which has many atoms, the supply amount of the pretreatment gas per unit time have to be increased compared to the supply amount of the source gas per unit time. That is, the supply amount of the pretreatment gas per unit time is increased compared to the supply amount of the source gas per unit time, so that all the ligand in the source gas may be configured to maximally react and be bonded with the second metal. Accordingly, all of the first metal may be separated from the ligand, generate a bonding product of the second metal and the ligand, and discharge the bonding product from the inside of the process chamber.

At this point, the ratio of the supply amount of the pretreatment gas to the supply amount of the source gas per unit time may be no more than approximately 1:10. That is, the supply amount of the pretreatment gas per unit time may not exceed approximately 10 times the supply amount of the source gas per unit time. When the supply amount of the pretreatment gas per unit time exceeds approximately 10 times the supply amount of the source gas per unit time, the second metal becomes more than the ligand and the second metal may be deposited on the substrate 10 and act as an impurity in the thin film.

The step S100 for supplying the source gas may be performed for a longer time period than the step S200 for supplying the pretreatment gas into the process chamber. That is, the time period for supplying the source gas may be longer than the time period for supplying the pretreatment gas. For example, before the source gas and the pretreatment gas are supplied together (co-flow), only the source gas is supplied, and the first metal may be caused to be deposited on the substrate than the second metal.

The step S100 for supplying the source gas may be performed earlier than the step S200 for supplying the pretreatment gas into the process chamber. That is, before the source gas and the pretreatment gas are supplied together (co-flow), only the source gas is supplied, and the first metal may be caused to be deposited earlier on the substrate than the second metal. Accordingly, it is not only possible to cause the second metal not to be deposited on the substrate 10 but to react with the ligand, but also possible to prevent the second metal from being deposited on the substrate 10. That is, the second metal may also be an atom (or matter) that may be deposited on the substrate. Thus, when the source gas and the pretreatment gas are started to be supplied together, the second metal may be deposited on the substrate and react with the reaction gas to form the byproduct film. In addition, the second metal may be contained in the thin film and act as an impurity.

However, when only the source gas is first supplied during a certain time period (or predetermined time period), it is possible to induce such that the first metal (layer) is first deposited on the substrate and only the first metal is deposited on the substrate. In addition, not only the ligand may be suppressed or prevented from being contained in the thin film by causing the second metal to disconnect, through the bonding with the ligand, the bonded ligand from the first metal that has been deposited in a state of being bonded with the ligand, but also the second metal may be prevented from being deposited on the substrate. Accordingly, the second metal may be induced to react only with the ligand, and the bonding product generated by the reaction (or bonding) of the second metal and the ligand may be discharged from the inside of the process chamber.

The second metal may have greater bonding energy with the ligand than the first metal. Large bonding energy between each other means that bonding is well established and is not easily disconnected, and small bonding energy means that bonding power is weak and is easily disconnected. The bonding energy between the second metal (e.g. Si) and the ligand (e.g. Cl) may be relatively greater than the bonding energy between the first metal (e.g. Ti) and the ligand (e.g. Cl). Therefore, the second metal reacts and is bonded with the ligand while the pretreatment gas (e.g. SiH₄) is supplied, so that a bonding product (e.g. SiCl₂) may be generated and the bonding between the first metal and the ligand which has relatively weak bonding energy may be disconnected. Accordingly, the first metal may be separated from the ligand.

Hereinafter, a thin film deposition method in accordance with still another exemplary embodiment will be described in more detail, and matters overlapping the portions described above relating to the thin film deposition apparatus in accordance with another exemplary embodiment, and related to the thin film deposition method in accordance with an exemplary embodiment will be omitted.

A thin film deposition method in accordance with another exemplary embodiment may include: step S10 for supplying a source gas including titanium (Ti) and a ligand into a process chamber to which a substrate is loaded; step S20 for supplying a pretreatment gas including silicon (Si) reactable with the ligand into the process chamber; and step S30 for supplying, into the process chamber, a reaction gas including a nitrogen atom (N) which reacts with titanium (Ti) and forms a titanium nitride (TiN) thin film.

First, a source gas including a first metal and a ligand is supplied into a process chamber to which a substrate is loaded (S10). The source gas may include titanium (Ti) and a ligand (e.g. chlorine element), be TiCl₄, and deposit titanium (Ti) (layer) on the substrate.

Next, a pretreatment gas including silicon (Si) reactable with the ligand is supplied into the process chamber (S20). The pretreatment gas may include silicon (Si) reactable with the ligand (e.g. chlorine element) and be silane (SiH₄). The silicon (Si) of the pretreatment gas may react with the ligand (e.g. Cl of TiCl₄) and generate a gas-phase bonding product (e.g. SiCl₂) and disconnect the boding between the titanium (Ti) and the ligand.

Next, a reaction gas including a nitrogen atom (N) which reacts with the titanium (Ti) and forms a titanium nitride (TiN) thin film is supplied into the process chamber (S30). The reaction gas may include a nitrogen atom (N) reacting with the titanium (Ti) to form a titanium nitride (TiN) thin film, and be ammonia (NH₃). At this point, a gas element (e.g. H) bonded with the nitrogen atom (N) may be separated from the nitrogen atom (N) and be present in a gas state, or may be bonded with the ligand (e.g. Cl) and generate a composite gas.

Accordingly, the bonding between the titanium (Ti) and the ligand may be effectively disconnected in the source gas, and the titanium (Ti) may be suppressed or prevented from being deposited in a state of being bonded with the ligand. Accordingly, the ligand such as chlorine atom (Cl) in the titanium nitride (TiN) thin film may be suppressed or prevented from being contained as an impurity, and the resistivity characteristics of the titanium nitride (TiN) thin film may be improved by reducing the resistivity of the titanium nitride (TiN) thin film.

As such, an exemplary embodiment includes a pretreatment gas nozzle part configured to supply a pretreatment gas including a second metal reacting with a ligand of a source gas, so that bonding between the first metal and the ligand may be effectively disconnected by supplying the pretreatment gas during a process for depositing a first metal. Thus, the first metal may be suppressed or prevented from being deposited in a state of being bonded with the ligand. Accordingly, the ligand may be suppressed or prevented from being contained in the thin film as an impurity, and the resistivity of the thin film may be improved by reducing the resistivity of the thin film. That is, the second metal of the pretreatment gas meets the source gas, disconnects the bonding between the first metal and the ligand and is bonded with the ligand, and thus, the bonding between the first metal and the ligand may be effectively disconnected. In addition, the first metal is effectively separated from the ligand, and the first metal deposited in a state of being bonded with the ligand may be minimized. In addition, the pretreatment gas and the reaction gas are separately supplied, so that the second metal may be prevented from reacting with the reaction gas and forming a byproduct film and only the first metal deposited on the substrate may be caused to react with the reaction gas. In addition, only the source gas is supplied before the predetermined gas is supplied and thus may cause the first metal to be deposited on the substrate earlier than the second metal. Accordingly, the second metal may be caused not to be deposited on the substrate and react with the ligand, and the second metal may be prevented from being deposited on the substrate. Meanwhile, the supply amount of the pretreatment gas per unit time is increased compared to the supply amount of the source gas per unit time, so that all the ligand in the source gas may be configured to maximally react and be bonded with the second metal. Thus, all of the first metal may be maximally separated from the ligand and discharge the bonding product from the inside of the process chamber. So far, preferred exemplary embodiments have been illustrated and described, but the present disclosure is not limited to the above-mentioned embodiments, and it will be understood to those skilled in the art to which the present disclosure belongs that various modifications and equivalent embodiments may be made from the present disclosure without departing from spirits and scopes of the present disclosure. Hence, the technical protective scope of the present invention shall be determined by the technical scope of the accompanying claims.

What is claimed is:

1. A thin film deposition apparatus comprising:
a process chamber configured to perform a deposition process for causing a first metal and a reactant source to react, to form a thin film on a substrate;
a source gas nozzle part configured to supply, into the process chamber, a source gas comprising the first metal and a ligand;
a pretreatment gas nozzle part configured to supply, into the process chamber, a pretreatment gas comprising a second metal reactable with the ligand; and
a reaction gas nozzle part configured to supply, into the process chamber, a reaction gas comprising the reactant source.

2. The thin film deposition apparatus of claim 1, wherein the reaction gas nozzle part supplies the reaction gas in a manner temporally separate from the source gas and the pretreatment gas.

3. The thin film deposition apparatus of claim 1, wherein the pretreatment gas nozzle part supplies the pretreatment gas during at least a portion of a time period the source gas nozzle part supplies the source gas.

4. The thin film deposition apparatus of claim 1, wherein the second metal has greater bonding energy with the ligand than the first metal.

5. The thin film deposition apparatus of claim 1, wherein a supply amount of the pretreatment gas per unit time is greater than a supply amount of the source gas per unit time.

6. A thin film deposition method comprising:
supplying a source gas comprising a first metal and a ligand into a process chamber to which a substrate is supplied;
supplying a pretreatment gas comprising a second metal reactable with the ligand into the process chamber; and
supplying, into the process chamber, a reaction gas comprising a reactant source which reacts with the first metal to form a thin film.

7. The thin film deposition method of claim 6, wherein the supplying of the source gas and the supplying of the reaction gas are alternately performed.

8. The thin film deposition method of claim 7, further comprising supplying a purge gas into the process chamber between the supplying of the source gas and the supplying of the reaction gas.

9. The thin film deposition method of claim 6, wherein the supplying of the pretreatment gas into the processing chamber is performed during at least a portion of a time period for supplying the source gas while performing the supplying of the source gas.

10. The thin film deposition method of claim 9, wherein the supplying of the pretreatment gas into the process chamber is performed while supplying a greater supply amount of the pretreatment gas than the source gas.

11. The thin film deposition method of claim 9, wherein the supplying of the source gas is performed for a longer time period than the supplying of the pretreatment gas into the processing chamber.

12. The thin film deposition method of claim 11, wherein the supplying of the source gas is performed earlier than the supplying of the pretreatment gas into the processing chamber.

13. The thin film deposition method of claim 6, wherein the second metal has greater bonding energy with the ligand than the first metal.

14. A thin film deposition method comprising:
supplying a source gas including titanium (Ti) and a ligand into a process chamber to which a substrate is loaded;
supplying a pretreatment gas including silicon (Si) reactable with the ligand into the process chamber; and
supplying, into the process chamber, a reaction gas comprising a nitrogen atom (N) which reacts with titanium (Ti) and forms a titanium nitride (TiN) thin film.
